(19) United States
(12) Patent Application Publication
(10) Pub. No.: US 2025/0285966 A1
(43) Pub. Date: Sep. 11, 2025

(54) SEMICONDUCTOR STRUCTURE AND METHOD FOR FORMING THE SAME

(71) Applicant: Winbond Electronics Corp., Taichung City (TW)

(72) Inventors: Pin-Hung CHEN, Tainan City (TW); Yu-Chun HUNG, Taichung City (TW)

(21) Appl. No.: 18/746,542

(22) Filed: Jun. 18, 2024

(30) Foreign Application Priority Data
Mar. 11, 2024 (TW) 113108865

(51) Int. Cl. H01L 23/528; H01L 21/768; H01L 23/532; H10B 12/00

(52) U.S. Cl. CPC H01L 23/528; H01L 21/76814; H01L 21/76877; H01L 23/53257; H10B 12/488

(57) ABSTRACT

A semiconductor structure and a method for forming the same are provided. The semiconductor structure includes a substrate and a word line structure. The word line structure is disposed in the substrate, and the word line structure includes a conductive stack. The conductive stack includes a first conductive layer and a second conductive layer, wherein the first conductive layer has higher etching resistance than the second conductive layer.

### CROSS REFERENCE TO RELATED APPLICATIONS

This application claims priority of Taiwan Patent Application No. 113108865, filed on Mar. 11, 2024, the entirety of which is incorporated by reference herein.

### BACKGROUND OF THE INVENTION

### Field of the Invention

The present invention relates to semiconductor structures and methods for forming the same, and in particular, it relates to semiconductor structures with conductive stacks and methods for forming the same.

### Description of the Related Art

As with the scaling down of semiconductor devices, memory sizes also continue to shrink, thereby leading to development of memory devices such as buried word lines that increase integration and improve performance. However, continued scaling down in sizes has resulted in defects such as seams in components, and the existence of defects makes adjacent components more susceptible to damage during the manufacturing process, thereby adversely affecting the performance of semiconductor devices.

### BRIEF SUMMARY OF THE INVENTION

The semiconductor structure provided herein includes substrate and word line structures. The word line structure is disposed in the substrate, and the word line structure includes a conductive stack. The conductive stack includes a first conductive layer and a second conductive layer, wherein the first conductive layer has higher etching resistance than the second conductive layer.

A method for forming a semiconductor structure provided herein includes the following steps. Provide substrate. Form a word line structure in the substrate, wherein forming the word line structure includes forming a conductive stack. Form the conductive stack, including: forming a first conductive layer; forming a second conductive layer above the first conductive layer; and performing an etching process to the second conductive layer to etch back a portion of the second conductive layer. The first conductive layer has higher etching resistance than the second conductive layer.

### BRIEF DESCRIPTION OF THE DRAWINGS

FIG. 1 is a schematic cross-sectional view illustrating a semiconductor structure according to some embodiments of the present disclosure.

FIGS. 2-5 respectively illustrate schematic cross-sectional views of a semiconductor structure at various stages of a formation method according to some embodiments of the present disclosure.

FIGS. 6A and 6B are respectively the analysis results of the second conductive layer and the first conductive layer analyzed by secondary ion mass spectrometry (SIMS) in some embodiments of the present disclosure.

### DETAILED DESCRIPTION OF THE INVENTION

In the manufacturing process of memory devices, the word line structure is usually formed by gap-filling with conductive materials. However, the conductive material layer filling with the existing process is often accompanied by large seams and poor etching resistance. As a result, in the subsequent etching back process, the etchant easily penetrates through the seams in the conductive material layer and damages the components under the conductive material layer, thereby causing damage or performance degradation of the semiconductor device.

To solve at least the above problems, the word line structure of the present disclosure includes a conductive stack formed by two different processes, wherein the lower layers of the conductive stack have higher etch resistance, thereby protecting underlying components from etchant damage during etch back process.

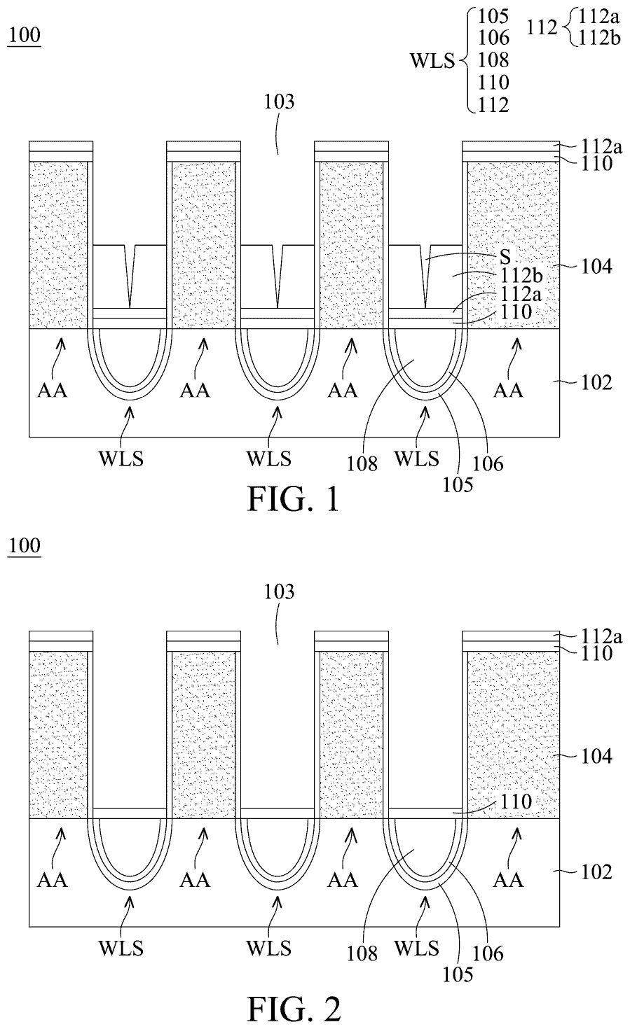

Refer to FIG. 1. The semiconductor structure 100 includes a substrate 102, a trench 103, a source/drain region 104, a dielectric layer 105, a lower liner 106, a third conductive layer 108, an upper liner 110, a first conductive layer 112a and a second conductive layer 112b. The first conductive layer 112a and the second conductive layer 112b may be collectively referred to as the conductive stack 112 hereinafter. The dielectric layer 105, the lower liner 106, the third conductive layer 108, the upper liner 110 and the conductive stack 112 may be collectively referred to as the word line structure WLS hereinafter. The description of the above components will be detailed in the subsequent sections through various manufacturing process stages.

Refer to FIG. 2. The semiconductor structure 100 includes substrate 102. In some embodiments, the substrate 102 may be a wafer such as a silicon wafer, a silicon-on-insulator (SOI) substrate, or a bulk semiconductor substrate. In some embodiments, substrate 102 may be a multilayer substrate or a gradient substrate. In some other embodiments, the substrate 102 may also be a doped or undoped semiconductor substrate.

In some embodiments, an isolation structure (not shown) is formed in the substrate 102 to define the active area AA.

In some embodiments, an ion implantation process is performed on the substrate 102 to form the source/drain regions 104. Specifically, the ion implantation process introduces n-type dopants (e.g., phosphorus) or p-type dopants (e.g., boron) into the active region AA to form the source/drain regions 104.

In some embodiments, word line structures WLS are formed in the substrate 102. The word line structure WLS may be a buried word line structure (bWL), so the top surface of the word line structure WLS may be lower than the top surface of the substrate 102. In some embodiments, after further processing is performed, the word line structure WLS may be used as a word line or a part of a word line of a dynamic random access memory (DRAM).

The dielectric layer 105 of the word line structure WLS serves as the gate dielectric layer. The third conductive layer 108 may be disposed on the dielectric layer 105 and fill the bottom of the trench 103. The lower liner 106 may be disposed between the third conductive layer 108 and the dielectric layer 105 to improve the interface compatibility between the third conductive layer 108 and the dielectric layer 105. In some embodiments, an upper liner 110 is further disposed on the third conductive layer 108 to improve the interface compatibility between the third conductive layer 108 and the conductive stack 112, which is subsequently disposed thereon. In some embodiments, the upper liner 110 and the lower liner 106 may collectively surround the third conductive layer 108 to separate the third conductive layer 108 from the conductive stack 112 to be disposed thereon. In other embodiments, the upper liner 110 and/or the lower liner 106 may also be optionally omitted.

Specifically, a patterning process may be performed on the semiconductor structure 100 to form the trench 103 in the substrate 102. Next, the dielectric layer 105 may be conformally formed on the sidewalls and bottom of the trench 103 through a deposition process. In some embodiments, the dielectric layer 105 may include an oxide such as silicon oxide, a nitride such as silicon nitride, an oxynitride such as silicon oxynitride, the like, or combinations thereof. In some embodiments, the dielectric layer 105 may be formed by chemical vapor deposition (CVD), atomic layer deposition (ALD), or thermal oxidation, but the present disclosure is not limited thereto. In one embodiment, the dielectric layer 105 may formed by a thermal oxidation process such as rapid thermal processing (RTP) using in-situ steam generation (ISSG) in the trench 103.

Following the above steps, after the dielectric layer 105 is formed, the lower liner 106 can be conformally formed on the dielectric layer 105 through a deposition process. In some embodiments, lower liner 106 may include a conductive material. For example, conductive materials may include polycrystalline silicon, amorphous silicon; metals such as tungsten, gold, silver, copper, cobalt, or the like; metal nitrides such as titanium nitride; conductive metal oxides, other suitable materials or combinations thereof. In one embodiment, the lower liner 106 may include titanium nitride. In some embodiments, the lower liner 106 may formed by physical vapor deposition (PVD), but the present disclosure is not limited thereto.

Following the above steps, after the lower liner 106 is formed, the third conductive layer 108 can be blanketly formed on the lower liner 106 by a deposition process. In some embodiments, the third conductive layer 108 may include conductive material. In one embodiment, the third conductive layer 108 may include tungsten (W). Next, the third conductive layer 108 and the lower liner 106 are etched back, leaving the remaining third conductive layer 108 and the lower liner 106 at the bottom of the trench 103. In one embodiment, the top surface of the third conductive layer 108 is leveled with the top surface of the lower liner 106. In some embodiments, the formation method of the third conductive layer 108 may include PVD, but the present disclosure is not limited thereto.

Next, an upper liner 110 can be formed on the upper surface of the third conductive layer 108 through a deposition process. In some embodiments, the upper liner 110 is also formed on the upper surface of the source/drain region 104. The material and formation method of the upper liner 110 may be the same as those of the lower liner 106, but the disclosure is not limited thereto. In one embodiment, the material of the upper liner 110 may include titanium nitride.

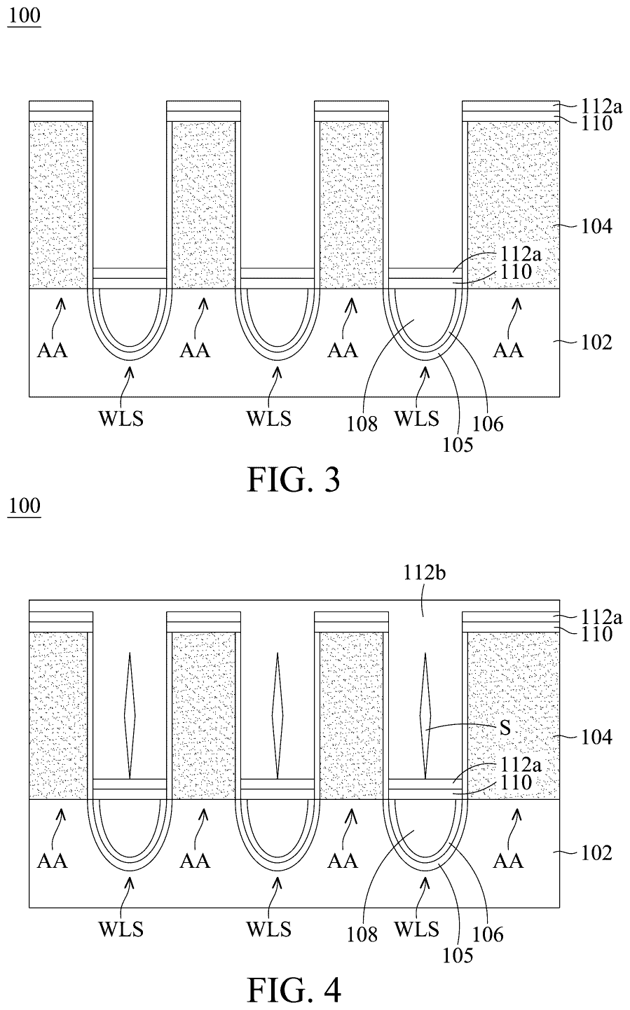

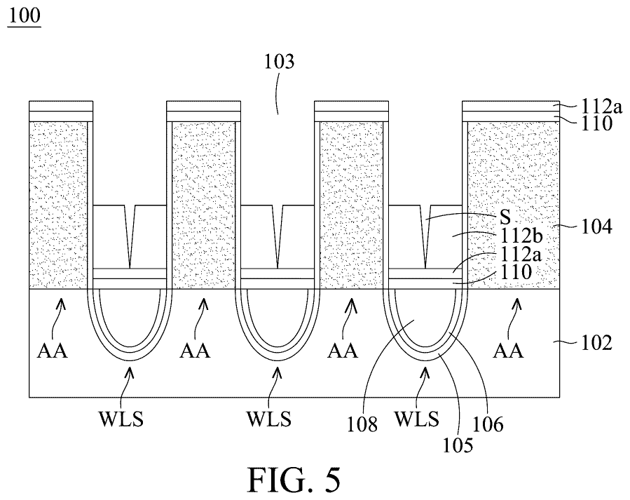

Refer to FIGS. 3-5. After the upper liner 110 is formed, a conductive stack 112 may be further formed on the upper liner 110 to serve as a gate conductive layer together with the third conductive layer 108. The material of the conductive stack 112 may be doped or undoped polysilicon, but the present disclosure is not limited thereto. Specifically, in some embodiments, the second conductive layer 112b may be doped or undoped polysilicon, and the first conductive layer 112a may be undoped polysilicon. In the present disclosure, forming the conductive stack 112 includes first depositing a relatively thin first conductive layer 112a with better etching resistance, and then depositing a relatively thick second conductive layer 112 with worse etching resistance to fill the trench 103. In some embodiments, the first conductive layer 112a (e.g., polysilicon) is deposited on the upper liner 110 by a method such as PVD, and then the second conductive layer 112b (e.g., polysilicon) is deposited on the first conductive layer 112a by a method such as CVD. In other words, the second conductive layer 112b and the first conductive layer 112a may be formed using similar or identical materials, but using different formation methods. The second conductive layer 112b and the first conductive layer 112a may have different properties, such as density, etching resistance, etc. Then, an etching process is applied to the second conductive layer 112b to etch the second conductive layer 112b to a desired level, as shown in FIG. 5.

In some embodiments, the aforementioned PVD to form the first conductive layer 112a may include sputtering, electron beam evaporation, etc. In some embodiments, the aforementioned CVD used to form the second conductive layer 112b may include low-pressure chemical vapor deposition (LPCVD), plasma-enhanced chemical vapor deposition (PECVD), etc. In some embodiments, the etching back process may be a dry etching process including fluorine-containing gas. For example, in one embodiment, the etching back process is a dry etching process including, CF₄, SF₆, CH₂F₂, CHF₃, and/or C₂F₆ or other fluorine-containing etchants.

In some embodiments, the first conductive layer 112a formed by PVD is denser and has fewer seams than the second conductive layer 112b formed by CVD, so that the first conductive layer 112a has higher etching resistance than the second conductive layer 112b. When the semiconductor structure 100 experiences the etching back process, the first conductive layer 112a protects the underlying upper liner 110 from being eroded by the etchant penetrating through the seam S in the second conductive layer 112b, which reduces device damage or performance degradation caused by the etchant penetrating into the seam S to damage the upper liner 110 and even further damaging the underlying third conductive layer 108.

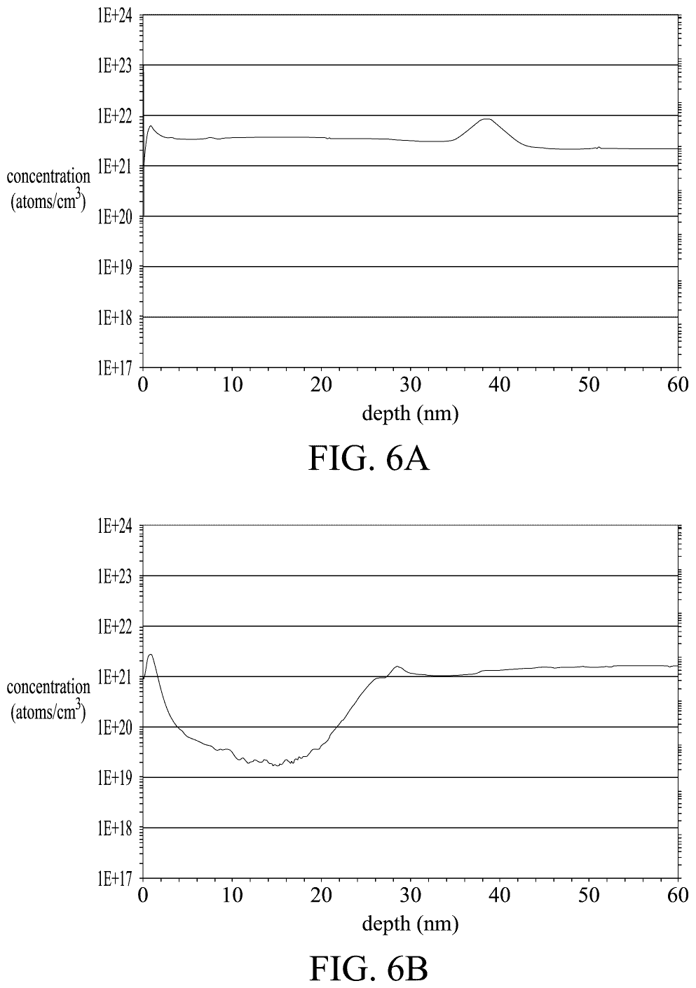

FIGS. 6A and 6B are respectively the analysis results of analyzing the second conductive layer 112b and the first conductive layer 112a by secondary ion mass spectrometry (SIMS) in some embodiments of the present disclosure. In some embodiments, the hydrogen ion [H] concentration of the first conductive layer 112a is less than the hydrogen ion [H] concentration of the second conductive layer 112b. It can be known from the results of FIG. 6A and FIG. 6B that the hydrogen ion concentration of the second conductive layer 112b is much higher than the hydrogen ion [H] concentration of the first conductive layer 112a. In some embodiments, the second conductive layer 112b is a polycrystalline silicon layer formed by CVD, and its hydrogen ion concentration is about 6×10²¹ atoms/cm³, and the first conductive layer 112a is a polycrystalline silicon layer formed by PVD, and its hydrogen ion concentration is about 4×10¹⁹ atoms/cm³. In other words, the ratio of the hydrogen ion concentration of the second conductive layer 112b to the hydrogen ion concentration of the first conductive layer 112a may be 100 or more, but the disclosure is not limited thereto.

Specifically, in some embodiments, the first conductive layer 112a is substantially free of hydrogen ions. The lower hydrogen ion concentration of the first conductive layer 112a makes its etching resistance higher than that of the second conductive layer 112b with a higher hydrogen ion concentration. In the embodiment where the first conductive layer 112a is a polycrystalline silicon layer formed by PVD and the second conductive layer 112b is a polycrystalline silicon layer formed by CVD. When the concentration of hydrogen ions in the second conductive layer 112b is high, the hydrogen ions will form Si—H and N—H bonds with silicon (Si) atoms and nitrogen (N) atoms in the film layer, respectively, thereby destroying the structure originally formed by silicon atoms and nitrogen atoms via Si—N bonds. This allows the silicon atoms to be removed by forming Si—F bonds without first breaking the Si—N bonds when the film is subjected to dry etching with fluorine-containing etchants (for example, CF₄, SF₆, CH₂F₂, CHF₃, and/or C₂F₆). This results in a polycrystalline silicon film layer with a higher hydrogen ion concentration being accompanied by lower etching resistance (i.e., higher etching rate).

For example, in some embodiments, during a dry etching process, the etching rate of the second conductive layer 112b formed by CVD caused by the etchant (for example, a CH4-based gas) is about 20% higher than that of the first conductive layer 112a formed by PVD. As a result, the first conductive layer 112a can prevent the etchant from penetrating through the seam S of the second conductive layer 112b and continuing to penetrate downward to damage the upper liner 110 or underlying elements during the etching back process.

Refer to FIGS. 4 and 5. In some embodiments, the second conductive layer 112b may have seams, and the first conductive layer 112 is substantially free of seams. In some embodiments, since the first conductive layer 112a is substantially free of seams, during the etching back process, even if the etchant penetrates into the film layer through the seams S of the second conductive layer 112b, it is less likely to penetrate through the first conductive layer 112a and further penetrate into the upper liner 110 or the third conductive layer 108 to cause damage thereto.

Refer to FIG. 5. In the present disclosure, the deposition process used to form the conductive stack 112 includes PVD and CVD, and the deposition rate of PVD is generally lower than the deposition rate of CVD. Therefore, in order to avoid the total time of the deposition process being too long, the thickness of the first conductive layer 112a formed by PVD may be appropriately controlled. When the thickness of the first conductive layer 112a is too thick, the overall process time may be too long due to the slow deposition rate of PVD. When the thickness of the first conductive layer 112a is too thin, the thickness may be insufficient to completely ensure that the underlying film layer is not damaged by the etchant during the etching back. For example, in some embodiments, the thickness of the first conductive layer 112a may range from 2 nm to 7 nm.

In summary, in embodiments of the present disclosure, forming the conductive stack includes forming the first conductive layer by PVD and forming the second conductive layer by CVD. The first conductive layer has a lower hydrogen concentration and fewer seams, so the first conductive layer has higher dry etching resistance than the second conductive layer. In subsequent processes such as etching back, the first conductive layer protects the underlying upper liner and even protects the underlying components from being eroded by the etchant penetrating through the seams in the second conductive layer. This reduces device damage or performance degradation caused by etchant seeping into the seam, damaging the upper liner and even further damaging the underlying third conductive layer.

For the sake of clarity and conciseness, only cross-sectional views of semiconductor structures during a part of the manufacturing process are shown herein for illustration and are not intended to impose any limitations on the present disclosure. For example, although not specifically mentioned herein, in some embodiments, a wet cleaning process may be performed before forming the first conductive layer to remove residue left by the previous process. Not only as mentioned above, a person of ordinary skill in the art will understand that any other appropriate process can be added before, after, or between the processes shown in the present disclosure.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate; and
a word line structure disposed in the substrate, wherein the word line structure comprises a conductive stack, and the conductive stack comprises:
a first conductive layer; and
a second conductive layer, wherein an etching resistance of the first conductive layer is higher than an etching resistance of the second conductive layer.

2. The semiconductor structure as claimed in claim 1, wherein a hydrogen ion concentration of the first conductive layer is less than a hydrogen ion concentration of the second conductive layer.

3. The semiconductor structure as claimed in claim 2, wherein a ratio of the hydrogen ion concentration of the second conductive layer to the hydrogen ion concentration of the first conductive layer is greater than 100.

4. The semiconductor structure as claimed in claim 1, wherein the second conductive layer has seams.

5. The semiconductor structure as claimed in claim 1, wherein the first conductive layer is substantially free of seams.

6. The semiconductor structure as claimed in claim 1, wherein the first conductive layer is formed by a physical vapor deposition process and the second conductive layer is formed by a chemical vapor deposition process.

7. The semiconductor structure as claimed in claim 1, wherein the word line structure further comprises:
an upper liner disposed under the first conductive layer and in direct contact with the first conductive layer;
a third conductive layer disposed under the upper liner;
a lower liner disposed under the third conductive layer; and
a dielectric layer disposed under the lower liner.

8. The semiconductor structure as claimed in claim 7, wherein the third conductive layer comprises tungsten.

9. A method for forming a semiconductor structure, comprising:
providing a substrate; and
forming a word line structure in the substrate, wherein forming the word line structure comprises:
forming a conductive stack, wherein forming the conductive stack comprises:
forming a first conductive layer;
forming a second conductive layer above the first conductive layer; and
performing an etching process to the second conductive layer to etch back a portion of the second conductive layer, wherein the first conductive layer has a higher etching resistance than the second conductive layer.

10. The method for forming a semiconductor structure as claimed in claim 9, wherein, prior to forming the conductive stack, forming the word line structure further comprises:
forming a trench in the substrate;
forming a dielectric layer in the trench;
forming a lower liner in the dielectric layer;
forming a third conductive layer above the lower liner; and
forming an upper liner above the third conductive layer,
wherein the conductive stack is formed on the upper liner and in direct contact with the upper liner.

11. The method for forming a semiconductor structure as claimed in claim 10, wherein the first conductive layer of the conductive stack protects the upper liner from etching during the etching process.

12. The method for forming a semiconductor structure as claimed in claim 10, wherein the third conductive layer comprises tungsten.

13. The method for forming a semiconductor structure as claimed in claim 9, wherein the step of performing the etching process comprises using a fluorine-containing gas.

14. The method for forming a semiconductor structure as claimed in claim 13, wherein the fluorine-containing gas comprises CF₄, SF₆, CH₂F₂, CHF₃, C₂F₆, or a combination thereof.

15. The method for forming a semiconductor structure as claimed in claim 9, wherein forming the conductive stack comprises:
performing a physical vapor deposition process to form the first conductive layer; and
performing a chemical vapor deposition process to form the second conductive layer.

16. The method for forming a semiconductor structure as claimed in claim 9, wherein a hydrogen ion concentration of the first conductive layer is less than a hydrogen ion concentration of the second conductive layer.

17. The method for forming a semiconductor structure as claimed in claim 16, wherein a ratio of the hydrogen ion concentration of the second conductive layer to the hydrogen ion concentration of the first conductive layer is greater than 100.

18. The method for forming a semiconductor structure as claimed in claim 9, further comprises performing a wet cleaning process before forming the first conductive layer.

19. The method for forming a semiconductor structure as claimed in claim 9, wherein the second conductive layer has seams.

20. The method for forming a semiconductor structure as claimed in claim 9, wherein the first conductive layer is substantially free of seams.
